(19) United States
(12) Patent Application Publication
(10) Pub. No.: US 2010/0320760 A1
(43) Pub. Date: Dec. 23, 2010

(54) Solar and Wind Power Generator Capable of Tracking Sunlight Automatically

(75) Inventors: Ching-Hui Yu, Jhubei City (TW); Chih-Chen Chen, Jhubei City (TW)

Correspondence Address: STITES & HARBISON PLLC, Suite 900, 1199 N. Fairfax Street, Alexandria, VA, 22314, US

(73) Assignee: Power Light Tech. Co., Ltd., Jhubei City (TW)

(21) Appl. No.: 12/534,884

(22) Filed: Aug. 4, 2009

(30) Foreign Application Priority Data
Jun. 22, 2009 (TW) 098120820

(51) Int. Cl. H02P 9/00; F03D 9/00; H01L 31/042

(52) U.S. Cl. 290/44; 290/55; 136/244

(57) ABSTRACT

A solar and wind power generator capable of tracking sunlight automatically is provided. The solar and wind power generator includes a base, a revolving column, a generator, a plurality of wind-collecting portions, a plurality of photovoltaic panels, and a secondary cell. The generator is disposed in the base. A wind-collecting element of each wind-collecting portion is coupled to the revolving column by a rotor brake. The revolving column is coupled to the generator. The wind-collecting elements, when driven by wind, rotate the revolving column so as for the generator to generate electric power. The photovoltaic panels are arranged on the wind-collecting elements to absorb sunlight and thereby generate electric power. Electric power generated by the generator and the photovoltaic panels is stored in the secondary cell. Inclination angles of the wind-collecting elements are adjustable by the rotor brakes, allowing the photovoltaic panels to face the sun and track sunlight automatically.

### BACKGROUND OF THE INVENTION

1. Technical Field

The present invention relates to solar and wind power generators capable of tracking sunlight automatically and, more particularly, to a solar and wind power generator capable of tracking sunlight automatically and applicable to power generation.

2. Description of Related Art

Electricity not only is an indispensable resource in our daily life but also plays a critical role in economic development. Nowadays, methods for generating electricity are generally divided into fossil fuel-fired power generation, nuclear power generation, and so on. However, fossil fuel-fired power generation, which relies on burning coal, petroleum, or liquefied natural gas, may lead to over-exploitation of resources and environmental pollution, and nuclear power generation is disadvantaged by potential radioactive leak and nuclear waste pollution. Therefore, many countries, seeing the so-called green energy, such as wind energy and solar energy, as the renewable energy of choice, have put plenty of resources into the research and development of power generation techniques based on wind energy and solar energy.

Presently, a common wind power generator essentially includes a generator provided in a base and a wind turbine coupled to a rotating shaft of the generator. When propelled by wind, the wind turbine is rotated and drives the rotating shaft of the generator synchronously so as for the generator to generate electric power. However, while wind power generators are capable of converting wind energy into electricity, it is necessary that the wind power generators be subjected to wind strong enough to propel the wind turbines. Therefore, the location of a wind power generator must be an appropriate combination of environmental, topographic, and seasonal conditions, which nevertheless limit the practicability of wind power generators in general. Moreover, as a wind power generator can only generate electricity from wind, power generation is unattainable when there is insufficient wind. As a result, wind power generators have yet to be used as major power generation equipment.

To overcome the aforesaid problems, power generation systems or devices driven by both wind and solar energy were developed, in which photovoltaic panels are integrated with wind turbines to enable power generation in the absence of either wind or sunlight, thereby increasing the efficiency of power generation. However, in existing wind and solar power generation systems or devices, the wind turbines can only operate with wind coming from particular directions and are not angularly adjustable in response to changes in wind direction; also, the photovoltaic panels integrated with the wind turbines can only receive sunlight from particular directions, too. Consequently, there is still room for improvement in the efficiency of these power generation systems or devices.

### BRIEF SUMMARY OF THE INVENTION

The present invention provides a solar and wind power generator capable of tracking sunlight automatically, wherein inclination angles of wind-collecting elements are adjustable by rotor brakes so as for photovoltaic panels to track sunlight and keep facing the sun, thereby allowing the photovoltaic panels to make efficient use of sunlight in power generation.

The present invention provides a solar and wind power generator capable of tracking sunlight automatically, wherein inclination angles of wind-collecting elements are adjustable according to the strength of wind or the intensity of sunlight, thereby putting the wind-collecting elements in positions fit for wind power generation or solar power generation.

To achieve the above and other effects, the present invention provides a solar and wind power generator capable of tracking sunlight automatically, wherein the solar and wind power generator includes: a base having a receiving space; a revolving column rotatably coupled to the base; a generator coupled to the revolving column and provided in the receiving space; a plurality of wind-collecting portions, each including a rotor brake and a wind-collecting element, wherein the rotor brake has a fixed end and a movable end movably coupled to the revolving column, and the wind-collecting element is coupled to the fixed end of the rotor brake, has an inclination angle adjustable by the rotor brake, and is rotatable by wind so as to drive the revolving column to rotate, thus driving the generator to generate electric power; a plurality of photovoltaic panels provided on the wind-collecting elements so as to absorb sunlight and thereby generate electric power; and a secondary cell provided in the receiving space and electrically connected to the generator and the photovoltaic panels so as to store electric power.

Implementation of the present invention at least involves the following inventive steps:

1. With the photovoltaic panels being provided on the wind-collecting elements, the generator can generate electric power from wind energy as well as solar energy, thereby increasing the efficiency of power generation.

2. With the inclination angles of the wind-collecting elements being adjustable by the rotor brakes, the photovoltaic panels can track sunlight and keep facing the sun so as to be efficiently used.

3. With the inclination angles of the wind-collecting elements being adjustable according to a sensing result of wind strength and sunlight intensity, the wind-collecting elements can be set at positions fit for wind power generation or solar power generation.

### BRIEF DESCRIPTION OF THE SEVERAL VIEWS OF THE DRAWINGS

The invention as well as a preferred mode of use, further objectives, and advantages thereof will be best understood by referring to the following detailed description of illustrative embodiments in conjunction with the accompanying drawings, wherein:

FIG. 1 is a perspective view of a solar and wind power generator capable of tracking sunlight automatically according to a first embodiment of the present invention;

FIG. 2 is a partially exploded perspective view of the solar and wind power generator capable of tracking sunlight automatically according to the first embodiment of the present invention;

FIG. 3 is a perspective view showing operation of the solar and wind power generator capable of tracking sunlight automatically according to the first embodiment of the present invention;

FIG. 4 is another perspective view showing operation of the solar and wind power generator capable of tracking sunlight automatically according to the first embodiment of the present invention;

FIG. 5 is a perspective view of a solar and wind power generator capable of tracking sunlight automatically according to a second embodiment of the present invention;

FIG. 6 is a circuit block diagram of a monitoring and controlling device according to the present invention; and

FIG. 7 is a flowchart of a control unit according to the present invention.

### DETAILED DESCRIPTION OF THE INVENTION

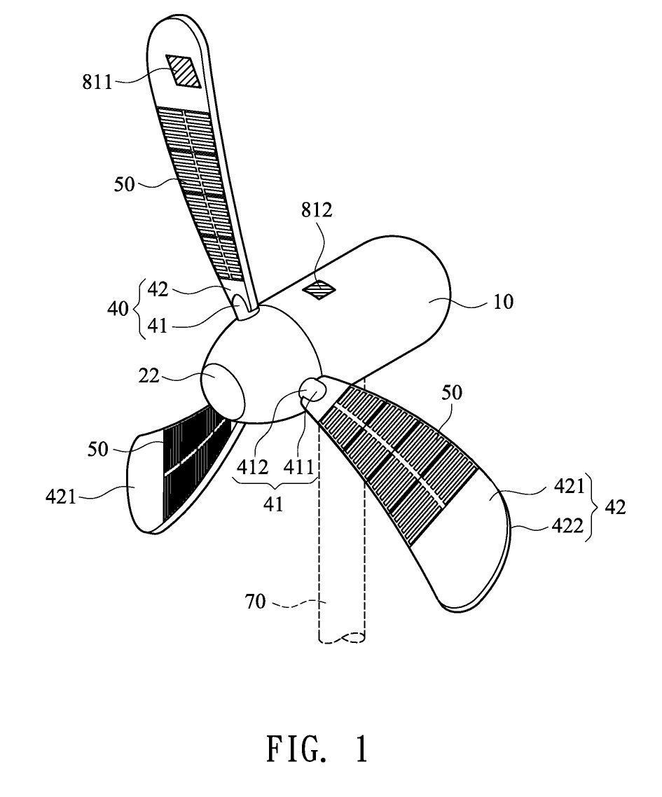

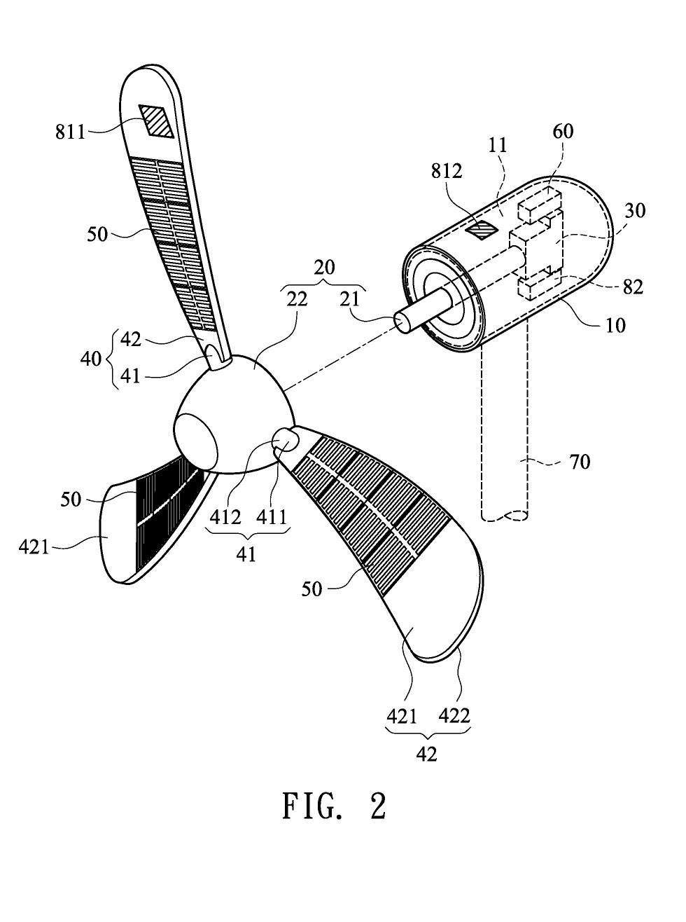

Referring to FIG. 1 and FIG. 2, a solar and wind power generator capable of tracking sunlight automatically according to a first embodiment of the present invention includes a base 10, a revolving column 20, a generator 30, a plurality of wind-collecting portions 40, a plurality of photovoltaic panels 50, and a secondary cell 60.

As shown in FIG. 2, the base 10 has a receiving space 11. The generator 30 and the secondary cell 60 are provided in the receiving space 11. The base 10 is further coupled to a post 70 for supporting the base 10, thus allowing the base 10 to be located at an elevated position.

Referring to FIG. 2, the revolving column 20 includes a rotating shaft 21 and a connecting portion 22. The rotating shaft 21 extends out of the base 10 and is rotatably coupled to the base 10. The connecting portion 22 is coupled to the rotating shaft 21 such that the connecting portion 22 is synchronously rotatable with the rotating shaft 21. In other words, both the rotating shaft 21 and the connecting portion 22 of the revolving column 20 are rotatably coupled to the base 10. It is also feasible that the revolving column 20 only includes the rotating shaft 21.

With reference to FIG. 2, the generator 30, which is generally defined as a generator for use with a wind-driven power generation device, is provided in the receiving space 11 of the base 10 and is coupled to the rotating shaft 21 of the revolving column 20. In consequence, rotation of the rotating shaft 21 of the revolving column 20 drives the generator 30 to generate electric power.

As shown in FIG. 2, the wind-collecting portion 40 includes a rotor brake 41 and a wind-collecting element 42.

The rotor brake 41 has a fixed end 411 and a movable end 412. The movable end 412 of the rotor brake 41 is coupled to the revolving column 20. More particularly, the movable end 412 is rotatably coupled to the revolving column 20. In other words, the movable end 412 of the rotor brake 41, though coupled to the revolving column 20, is rotatable. For instance, the revolving column 20 may include a stator while the movable end 412 of the rotor brake 41 has an end portion provided with a rotor, wherein the rotor is coupled to the stator of the revolving column 20 so as for the rotor brake 41 to rotate around an axis defined by the stator of the revolving column 20 (not shown). Besides, as shown in FIG. 2, when the revolving column 20 includes the connecting portion 22, the movable end 412 of the rotor brake 41 is coupled to the connecting portion 22 of the revolving column 20. However, if the revolving column 20 only includes the rotating shaft 21, the movable end 412 of the rotor brake 41 is directly coupled to the rotating shaft 21 (not shown).

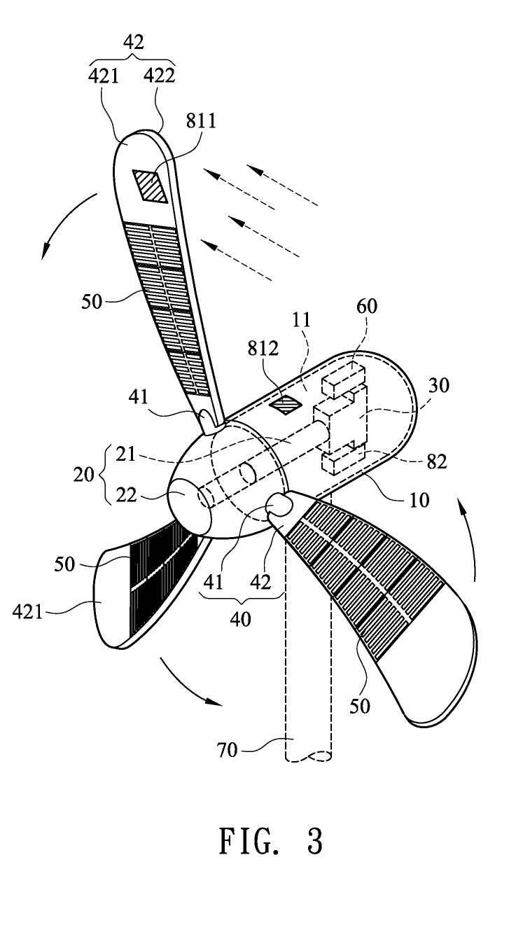

The wind-collecting element 42 is fixedly coupled to the fixed end 411 of the rotor brake 41. As the movable end 412 of the rotor brake 41 is rotatably coupled to the revolving column 20, an inclination angle of the wind-collecting element 42 can be adjusted by rotating the rotor brake 41. Referring to FIG. 3, the wind-collecting element 42 has a windward side 421 and a leeward side 422, wherein the leeward side 422 is the side opposite the windward side 421. The windward side 421 of the wind-collecting element 42 can so positioned as to face a direction in which wind blows with relatively high strength such that the wind hits and rotates the wind-collecting element 42. Consequently, the wind-collecting element 42 drives the revolving column 20 to rotate, thereby driving the generator 30 to generate electric power. Furthermore, by adjusting the inclination angle of the wind-collecting element 42 to an optimal angle fit for wind power generation, the generator 30 is allowed to generate more electric power.

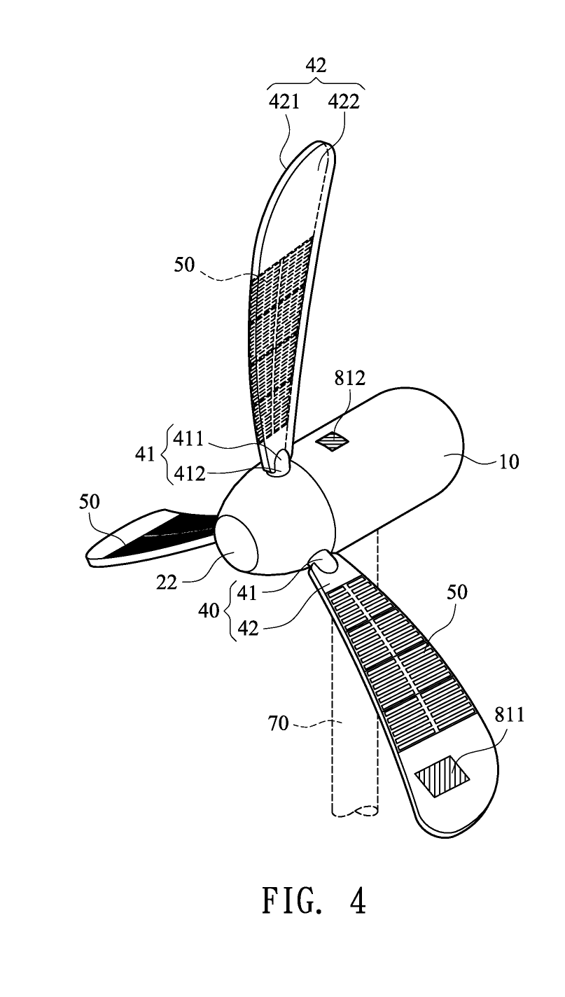

Referring to FIG. 2, the photovoltaic panel 50 is a thin-film photovoltaic panel and may be replaced as appropriate by a crystalline-silicon photovoltaic panel, an electrochemical photovoltaic panel, or a compound-semiconductor photovoltaic panel. As shown in FIGS. 1 through 5, the photovoltaic panels 50 are arranged on the windward sides 421 of the wind-collecting elements 42 so as to absorb sunlight and thereby generate electric power. As shown in FIG. 4, with the incident angle of sunlight varying with time and season, the inclination angles of the wind-collecting elements 42 can be adjusted by the rotor brakes 41 so as to make efficient use of the photovoltaic panels 50 in solar power generation. Thus, when wind power generation is unattainable due to a lack of wind, all the photovoltaic panels 50 can be turned to the sun for solar power generation.

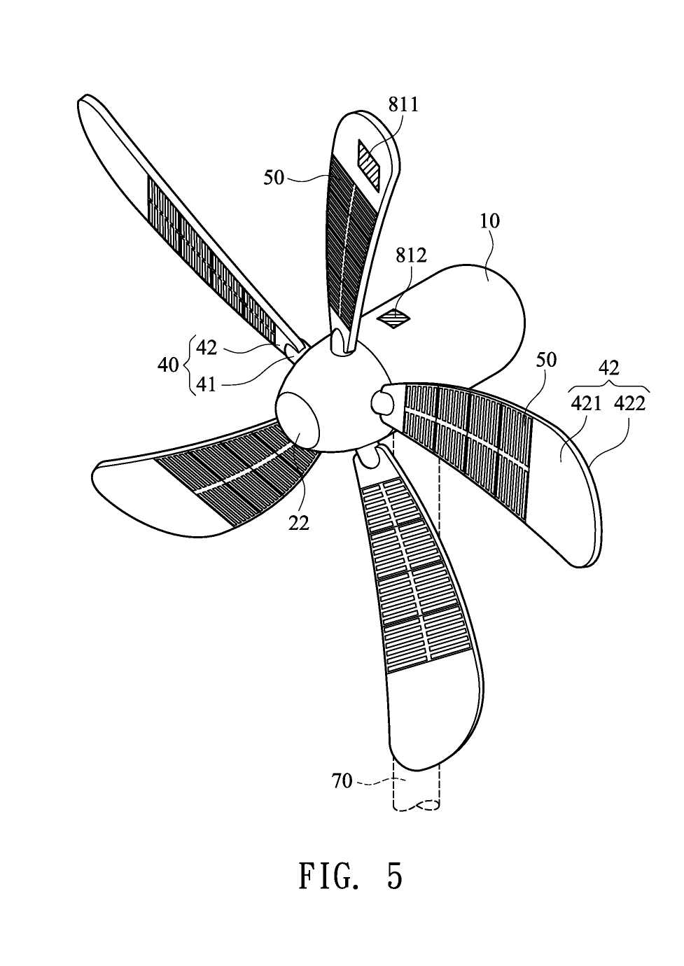

As shown in FIG. 5, a solar and wind power generator capable of tracking sunlight automatically according to a second embodiment of the present invention includes five wind-collecting portions 40. Therefore, compared with the first embodiment in which only three wind-collecting portions 40 are provided, there are more photovoltaic panels 50 in the second embodiment for solar power generation, and consequently more electric power to be generated from solar energy. From the perspective of wind power generation, the number of the wind-collecting elements 42 may also be increased such that the wind-collecting elements 42 are propelled by a greater amount of wind, thus enhancing the efficiency of wind power generation.

As shown in FIG. 2 and FIG. 3, the secondary cell 60 is provided in the receiving space 11 and is electrically connected to the generator 30 and the photovoltaic panels 50 so as for electric power generated by the generator 30 and the photovoltaic panels 50 to be stored in the secondary cell 60.

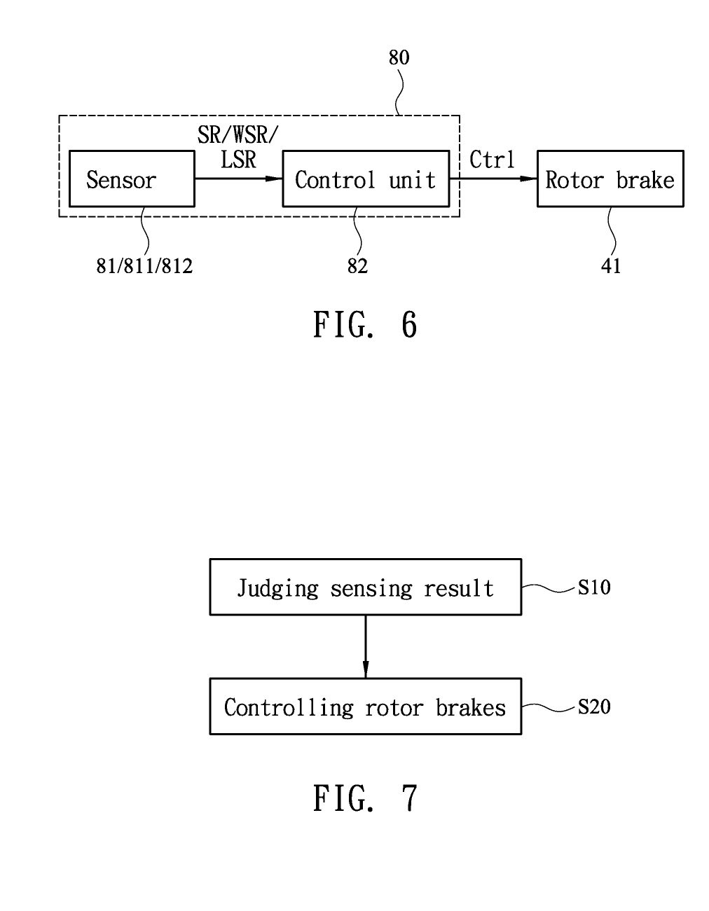

Referring to FIG. 6, in order to precisely control the inclination angles of the wind-collecting elements 42, the solar and wind power generator of the present invention further includes a monitoring and controlling device 80. The monitoring and controlling device 80 includes a sensor 81 and a control unit 82.

As shown in FIGS. 1 through 5, the sensor 81 is implemented by a wind sensor 811 and a photosensor 812. The wind sensor 811 is provided on one of the wind-collecting portions 40 so as to sense wind strength precisely and generate a wind sensing result WSR. The photosensor 812 is provided at the base 10 or, alternatively, at the connecting portion 22 or the rotating shaft 21 of the revolving column 20 (not shown), thus allowing the photosensor 812 to sense light intensity and generate a light sensing result LSR.

As shown in FIG. 2 and FIG. 3, the control unit 82 is provided in the receiving space 11 of the base 10 and is connected in electrical signal communication with the sensor 81 and the rotor brakes 41. Thus, the rotor brakes 41 are controlled according to the wind sensing result WSR or the light sensing result LSR so as to adjust the inclination angles of the wind-collecting elements 42. Referring to FIG. 7, the control unit 82 executes the steps of judging a sensing result (S10) and controlling the rotor brakes 41 (S20).

At the step of judging a sensing result (S10), as shown in FIG. 6, the control unit 82 receives a sensing result SR output by the sensor 81, such as the wind sensing result WSR or the light sensing result LSR, and judges the sensing result SR so as to output a control signal Ctrl. For instance, if the value of the wind sensing result WSR output by the wind sensor 811 is greater than a wind strength threshold value, indicating the presence of relatively strong wind and therefore the feasibility of wind power generation, the control unit 82 will output a corresponding control signal Ctrl to the rotor brakes 41. If the value of the light sensing result LSR output by the photosensor 812 is greater than a light intensity threshold value, indicating the presence of relatively strong light and therefore the feasibility of solar power generation, the control unit 82 will also output a corresponding control signal Ctrl to the rotor brakes 41.

The step of controlling the rotor brakes (S20) is described in detail in this and the following paragraphs. As shown in FIG. 3, when the wind sensing result WSR indicates the feasibility of wind power generation, the rotor brakes 41 are controlled by the control unit 82 via the control signal Ctrl generated according to the wind sensing result WSR, so as to adjust the inclination angles of the wind-collecting elements 42 to an optimal angle for wind power generation. In other words, the windward sides 421 of the wind-collecting elements 42 are rotated to a direction of relatively high wind strength to increase the efficiency of wind power generation.

With reference to FIG. 4, when the light sensing result LSR indicates the feasibility of solar power generation, the rotor brakes 41 are controlled by the control unit 82 via the control signal Ctrl generated according to the light sensing result LSR, so as to rotate the windward sides 421 of the wind-collecting elements 42 to a direction of relatively strong sunlight. In other words, the inclination angles of the wind-collecting elements 42 are adjusted to an optimal angle for solar power generation such that all the photovoltaic panels 50 are turned to the sun and therefore efficiently used in solar power generation.

In short, the rotor brakes 41 coupled to the wind-collecting elements 42 allow the inclination angles of the wind-collecting elements 42 to be adjustable. Therefore, when wind is strong, the wind-collecting elements 42 are rotated as appropriate, and wind power generation takes place. However, when sunlight is strong, the wind-collecting elements 42 are rotated accordingly such that solar power generation takes place. By making efficient use of both wind and sunlight, the efficiency of power generation is enhanced.

The foregoing embodiments are illustrative of the characteristics of the present invention so as to enable a person skilled in the art to understand the disclosed subject matter and implement the present invention accordingly. The embodiments, however, are not intended to restrict the scope of the present invention. Hence, all equivalent modifications and variations made in the foregoing embodiments without departing from the spirit and principle of the present invention should fall within the scope of the appended claims.

What is claimed is:

1. A solar and wind power generator capable of tracking sunlight automatically, comprising:
a base having a receiving space;
a revolving column rotatably coupled to the base;
a generator coupled to the revolving column and provided in the receiving space;
a plurality of wind-collecting portions, each comprising:
a rotor brake having a fixed end and a movable end, the movable end being coupled to the revolving column; and
a wind-collecting element coupled to the fixed end of the rotor brake, the wind-collecting element having an inclination angle adjustable by the rotor brake, and the wind-collecting element being rotatable by wind so as to drive the revolving column to rotate, thus driving the generator to generate electric power;
a plurality of photovoltaic panels provided on the wind-collecting elements so as to absorb sunlight and thereby generate electric power; and
a secondary cell provided in the receiving space and electrically connected to the generator and the photovoltaic panels so as to store electric power.

2. The solar and wind power generator of claim 1, wherein each said wind-collecting element has a windward side and a leeward side opposite the windward side, and the photovoltaic panels are provided on the windward sides.

3. The solar and wind power generator of claim 1, wherein the photovoltaic panels are thin-film photovoltaic panels.

4. The solar and wind power generator of claim 1, further comprising a monitoring and controlling device comprising:
a sensor for sensing a strength of the wind or an intensity of the sunlight so as to generate a sensing result; and
a control unit provided in the receiving space and connected in electrical signal communication with the sensor and the rotor brakes so as to control the rotor brakes according to the sensing result, thereby adjusting the inclination angles of the wind-collecting elements.

5. The solar and wind power generator of claim 4, wherein the sensor is a wind sensor provided at a said wind-collecting portion.

6. The solar and wind power generator of claim 4, wherein the sensor is a photosensor provided at the base or at the revolving column.

7. The solar and wind power generator of claim 4, wherein the control unit executes steps of judging the sensing result and controlling the rotor brakes according to the sensing result, thereby adjusting the inclination angles of the wind-collecting elements to an optimal angle for wind power generation or an optimal angle for solar power generation.
